(19) United States
(12) Patent Application Publication
(10) Pub. No.: US 2023/0003233 A1
(43) Pub. Date: Jan. 5, 2023

(54) SERIES FAN FRAME BODY STRUCTURE

(71) Applicant: ASIA VITAL COMPONENTS CO., LTD., New Taipei City (TW)

(72) Inventors: Bor-Haw Chang, New Taipei City (TW); Yu-Tzu Chen, New Taipei City (TW); Chung-Shu Wang, New Taipei City (TW)

(21) Appl. No.: 17/941,131

(22) Filed: Sep. 9, 2022

Related U.S. Application Data
(63) Continuation-in-part of application No. 15/369,844, filed on Dec. 5, 2016.

(51) Int. Cl. F04D 29/52; H02K 9/04; F04D 25/16; H05K 7/20

(52) U.S. Cl. CPC F04D 29/52; H02K 9/04; F04D 25/16; H05K 7/20

(57) ABSTRACT

A series fan frame body structure includes a first fan frame body, a second fan frame body and a serial connection frame body. The serial connection frame body has a first opening and a second opening. The first and second openings arranged in nonparallel to each other. The first and second fan frame bodies are respectively disposed at the first and second openings. The first and second fan frame bodies are inclined from each other. The first and second fan frame bodies are serially connected in a nonparallel form. Therefore, in the system, due to the resistance of the structure with such configuration, the audio frequency dipole structure is destructed so that the periodical noise and vibration characteristic are lowered.

The present application is a continuation in part of U.S. patent application Ser. No. 15/369,844 filed on Dec. 5, 2016.

### BACKGROUND OF THE INVENTION

### 1. Field of the Invention

The present invention relates generally to a series fan frame body structure, and more particularly to a fan frame body structure in which two fans are serially connected in a nonparallel form.

### 2. Description of the Related Art

A fan can provide forced cooling effect. Therefore, the fan is irreplaceably applied to the server of a large-scale storage device to play a decisive role in heat dissipation. A high-performance fan not only can save power, but also can enhance the stability of the operation of the device. Moreover, it has become one of the competitive issues of fan manufacturers how to design low-noise fan products.

In recent years, due to the change of the market and the trend to develop future cloud system, the cloud system has a requirement for the fans that is different from the other fields. First, the performance of the fans applied to the cloud system is required to be 10% or even 15% higher than the other fields. This is because in the cloud and network communication system, the unit operation density is extremely high and the operation conditions of the chassis and the power supply are much stricter than any other environment. Moreover, the operation of the cloud system always 24-hour continues without interruption. Therefore, the requirements of the cloud system for stability, heat dissipation ability and noise control are much higher than a common system.

With respect to a high-density large-scale server, it is necessary to use a fan tray to provide strong airflow for achieving the object of heat dissipation. Therefore, in practice, there is a system of serially connected fan trays. Multiple sets of serially connected fans are further combined in parallel to form a large-scale fan tray system so as to achieve the object of heat dissipation.

In the internal space of the server, the hard disk device such as HDD is generally positioned right in front of the fan tray. The other heat generation components such as the CPU/GPU, DIMMs, memory card or the control panel are positioned right behind the fan tray. In this case, the direction of the flow field is nearly lined up with the respective components. Accordingly, the airflow will flow through the space of the hard disk on the front side into the blades of the heat dissipation fan and then exhaust to the rear side. As a result, the blades of the heat dissipation fan will periodically bear the pulse effect of the non-uniform airflows at the inlet and the outlet. This will make regular dipole noise to create louder periodical noise. The higher the requirement for the performance and heat dissipation effect is, the greater the extent to which the fan is affected by the development of the dipole is and the louder the periodical noise is.

Due to the dipole development of noise, after combined in parallel, the pairs of conventional fans generally will interact on each other to synergize the noise. Therefore, the periodical noise will become more serious. It is therefore tried by the applicant to provide a fan frame body structure and a fan with the fan frame body structure to solve the problem of noise or vibration caused after the fans are serially connected or combined in parallel.

### SUMMARY OF THE INVENTION

It is therefore a primary object of the present invention to provide a series fan frame body structure, in which a first axis of a first fan frame body extends from a first opening of a serial connection frame body into a closed communication passage of the serial connection frame body and a second axis of a second fan frame body extends from a second opening of the serial connection frame body into the closed communication passage of the serial connection frame body. The first axis and the second axis intersect each other to contain an obtuse angle so as to destroy the structure of the audio frequency dipole produced by the noise and reduce vibration.

It is a further object of the present invention to provide the above series fan frame body structure, which has a serial connection frame body having a trapezoidal closed peripheral frame serially connected between the first and second fan frame bodies in nonparallel to each other so as to destroy the structure of the audio frequency dipole produced by the noise and reduce vibration.

To achieve the above and other objects, the series fan frame body structure of the present invention includes: a first fan frame body having a first passage and a first bearing cup seat, the first bearing cup seat having a first axis extending from a center of the first bearing cup seat; a second fan frame body having a second passage and a second bearing cup seat, the second bearing cup seat having a second axis extending from a center of the second bearing cup seat; and a serial connection frame body disposed between the first fan frame body and the second fan frame body. The serial connection frame body has a surrounding closed peripheral frame. The closed peripheral frame defines therein a closed communication passage. Two ends of the closed communication passage respectively have a first opening and a second opening arranged in nonparallel to each other. The first and second fan frame bodies are respectively disposed at the first and second openings. The closed communication passage is in communication with the first and second passages to together form a nonlinear closed airflow passage. The first and second axes extend into the closed communication passage of the serial connection frame body to intersect each other and contain an obtuse angle, whereby the first fan frame body and the second fan frame body are serially connected in nonparallel to each other. By means of the nonlinear closed airflow passage, the incoming and outgoing directions of the airflow are changed so as to change the audio frequency property and reduce the periodical interference effect.

In the present invention, the first and second bearing cup seats are arranged in a nonparallel form. Therefore, in the system, due to the resistance of the structure with such configuration, the audio frequency dipole structure is destructed so that the periodical noise and vibration characteristic are lowered.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of the fan frame body structure of the present invention;

FIG. 2 is a sectional assembled view of the fan frame body structure of the present invention;

FIG. 3 is a sectional assembled view of the fan frame body structure of the present invention;

FIG. 4 is a sectional assembled view showing that the fan frame body structure of the present invention is applied to a fan.

### DETAILED DESCRIPTION OF THE PREFERRED EMBODIMENTS

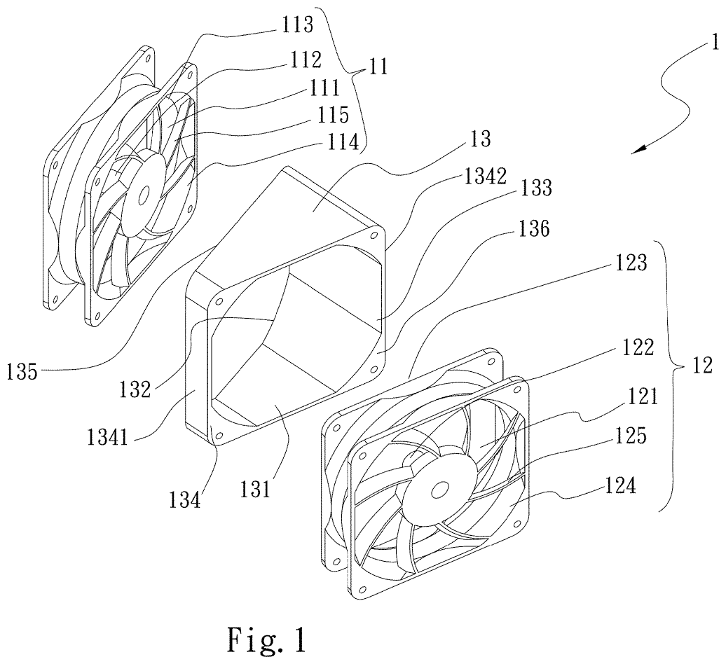

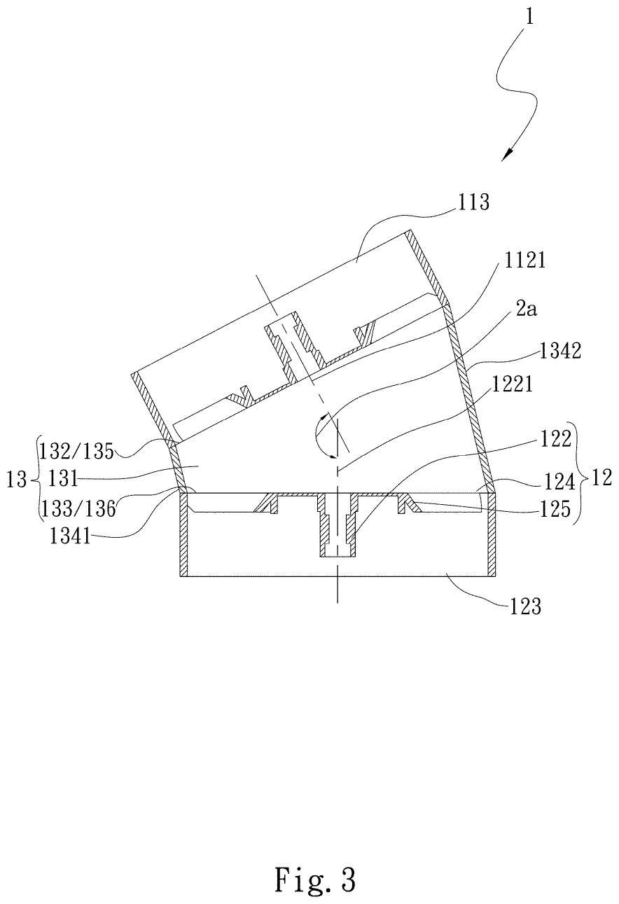

Please refer to FIGS. 1 and 3. FIG. 1 is a perspective exploded view of the fan frame body structure of the present invention. FIG. 3 is a sectional assembled view of the fan frame body structure of the present invention. As shown in the drawings, the series fan frame body structure 1 of the present invention includes a first fan frame body 11, a second fan frame body 12 and a serial connection frame body 13.

The first fan frame body 11 has a first passage 111 and a first bearing cup seat 112. The first bearing cup seat 112 and the first passage 111 are normal to each other. The first bearing cup seat 112 has a first axis 1121. The first passage 111 is formed in the first fan frame body 11.

The second fan frame body 12 has a second passage 121 and a second bearing cup seat 122. The second bearing cup seat 122 and the second passage 121 are normal to each other. The second bearing cup seat 122 has a second axis 1221. The second passage 121 is formed in the second fan frame body 12.

The serial connection frame body 13 is disposed between the first fan frame body 11 and the second fan frame body 12. The serial connection frame body 13 has a trapezoidal closed peripheral frame 134. The trapezoidal closed peripheral frame 134 has a trapezoidal configuration and a short side 1341 and a long side 1342 in parallel to each other. An inclined face 135 and a non-inclined face 136 are connected between the short side 1341 and the long side 1342 in nonparallel to each other as two opposite faces of the serial connection frame body 13. In addition, the trapezoidal closed peripheral frame 134 defines an internal closed communication passage 131. Two ends of the internal closed communication passage 131 respectively form a first opening 132 and a second opening 133 on the inclined face 135 and the non-inclined face 136. The first opening 132 is positioned on the inclined face 135 corresponding to the first fan frame body 11. The second opening 133 is positioned on the non-inclined face 136 corresponding to the second fan frame body 12. The first opening 132 and the second opening 133 are disposed in nonparallel to each other. The first fan frame body 11 and the second fan frame body 12 are respectively disposed at the first and second openings 132, 133. The closed communication passage 131 is in communication with the first and second passages 111, 112.

The first fan frame body 11 further has a first inlet 113 and a first outlet 114. The first inlet 113 and first outlet 114 are respectively positioned at two ends of the first passage 111. Multiple first connection bodies 115 extend from a circumference of the first bearing cup seat 112. The first connection bodies 115 can be static blades or ribs. The first connection bodies 115 are connected to an inner circumference of the first fan frame body 11. The second fan frame body 12 further has a second inlet 123 and a second outlet 124. The second inlet 123 and second outlet 124 are respectively positioned at two ends of the second passage 121. Multiple second connection bodies 125 extend from a circumference of the second bearing cup seat 122. The second connection bodies 125 can be static blades or ribs. The second connection bodies 125 are connected to an inner circumference of the second fan frame body 12.

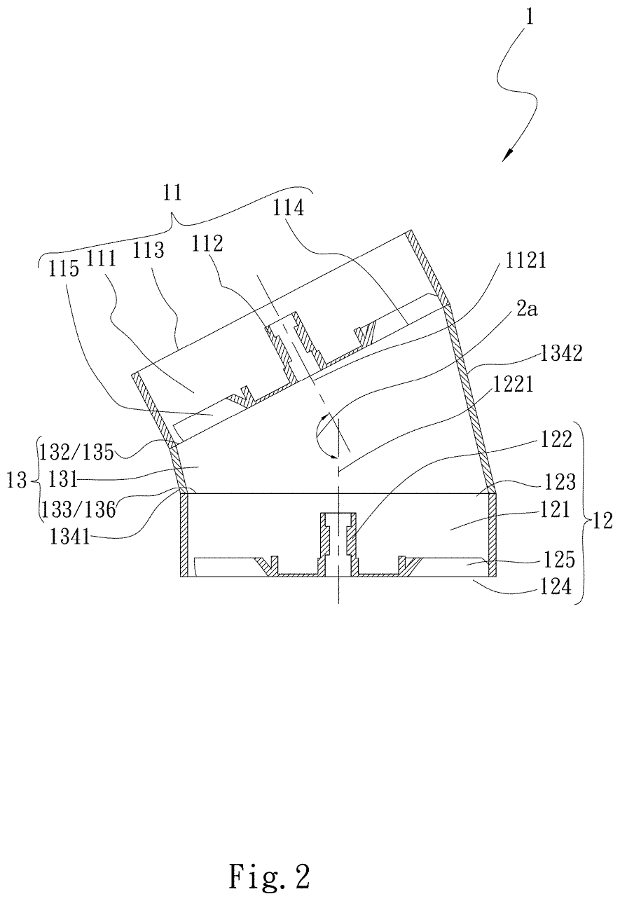

The first outlet 114 of the first fan frame body 11 is mated with the first opening 132 of the serial connection frame body 13. The second inlet 123 or the second outlet 124 of the second fan frame body 12 is mated with the second opening 133 of the serial connection frame body 13 (as shown in FIGS. 2 and 3).

To speak more specifically, the first axis 1121 of the first fan frame body 11 extends from the center of the first bearing cup seat 112 in an axial direction of the first fan frame body 11 to the first opening 132 of the serial connection frame body 13. The second axis 1221 of the second fan frame body 12 extends from the center of the second bearing cup seat 122 in an axial direction of the second fan frame body 12 to the second opening 133 of the serial connection frame body 13. The first axis 1121 of the first fan frame body 11 extends through the first opening 132 of the serial connection frame body 13 into the closed communication passage 131 of the serial connection frame body 13. The second axis 1221 of the second fan frame body 12 extends through the second opening 133 of the serial connection frame body 13 into the closed communication passage 131 of the serial connection frame body 13. The first axis 1121 and the second axis 1221 intersect each other in the closed communication passage 131 to contain an obtuse angle 2a, which preferably ranges from 91 to 179 degrees. Accordingly, the first fan frame body 11 and the second fan frame body 12 are serially connected in nonparallel to each other. In addition, the closed communication passage 131, the first passage 111 and the second passage 121 together form a nonlinear closed airflow passage.

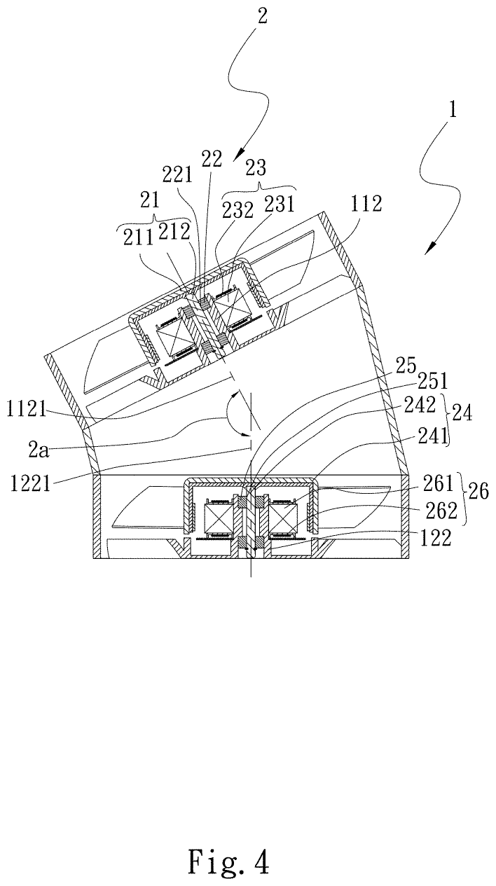

Please now refer to FIG. 4, which is a sectional assembled view showing that the fan frame body structure of the present invention is applied to a fan. The fan 2 includes a first rotor assembly 21, a first bearing 22, a first stator assembly 23, a second rotor assembly 24, a second bearing 25 and a second stator assembly 26.

The first rotor assembly 21 has a first fan hub 211 and a first shaft 212. The first fan hub 211 and the first shaft 212 are normal to each other. The first bearing 22 has a first shaft hole 221. The first bearing 22 is disposed in the first bearing cup seat 112. The first shaft 212 is rotatably connected in the first shaft hole 221. The first stator assembly 23 has multiple silicon steel sheets 231 and multiple windings 232 wound around the silicon steel sheets 231. The first stator assembly 23 is fitted around the first bearing cup seat 112.

The second rotor assembly 24 has a second fan hub 241 and a second shaft 242. The second fan hub 241 and the second shaft 242 are normal to each other. The second bearing 25 has a second shaft hole 251. The second bearing 25 is disposed in the second bearing cup seat 122. The second shaft 242 is rotatably connected in the second shaft hole 251. The second stator assembly 26 has multiple silicon steel sheets 261 and multiple windings 262 wound around the silicon steel sheets 261. The second stator assembly 26 is fitted around the second bearing cup seat 122.

The first fan frame body 11, the serial connection frame body 13 and the second fan frame body 12 can be serially securely integrally connected with each other by means of adhesion, press fit, fusion, engagement or locking of locking members.

In the series fan frame body structure of the present invention, the serial connection frame body 13 has a trapezoidal closed peripheral frame 134. The trapezoidal closed peripheral frame 134 defines an internal closed communication passage 131 in communication with the first and second passages 111, 112. The first axis 1121 and the second axis 1221 of the first and second fan frame bodies 11, 12 extend into the closed communication passage 131 of the serial connection frame body 13 and intersect each other to contain an obtuse angle 2a, whereby the first fan frame body 11 and the second fan frame body 12 are serially connected in nonparallel to each other to together form a nonlinear closed airflow passage. Accordingly, the incoming and outgoing directions of the airflow are changed. Under such circumstance, the development of the audio frequency of the dipole is destroyed to reduce the periodical noise energy. After serially connected, the structure of the fan is changed so that the directions of the airflow of the inlet and the outlet of the entire fan are also changed. Under such circumstance, the audio frequency property is changed to reduce the periodical interference effect. As a result, the periodical noise is lowered. The structure of the fan of the present invention is optimized to be different from the conventional fan structure. This can change the inherent frequency of the fan as a whole.

The present invention is not limited to one single set of series fan. The present invention can also achieve the same effect for multiple sets of series fans, which are combined in parallel.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A series fan frame body structure comprising:
a first fan frame body having a first passage and a first bearing cup seat, the first bearing cup seat having a first axis extending from a center of the first bearing cup seat;
a second fan frame body having a second passage and a second bearing cup seat, the second bearing cup seat having a second axis extending from a center of the second bearing cup seat; and
a serial connection frame body disposed between the first fan frame body and the second fan frame body, the serial connection frame body having a trapezoidal closed peripheral frame, the trapezoidal closed peripheral frame defining therein an internal closed communication passage, two ends of the closed communication passage respectively having a first opening and a second opening arranged in nonparallel to each other, the first and second fan frame bodies being respectively disposed at the first and second openings, the closed communication passage being in communication with the first and second passages, the first and second axes respectively extending from the first and second openings of the serial connection frame body into the closed communication passage to intersect each other and contain an obtuse angle, whereby the first fan frame body and the second fan frame body are serially connected in nonparallel to each other and the closed communication passage, the first passage and the second passage together form a nonlinear closed airflow passage so as to change incoming and outgoing directions of the airflow and further destroy the structure of the audio frequency dipole produced by the noise and reduce vibration.

2. The series fan frame body structure as claimed in claim 1, wherein the first fan frame body further has a first inlet and a first outlet, the first inlet and first outlet being respectively positioned at two ends of the first passage, the first outlet being mated with the first opening of the serial connection frame body, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second inlet being mated with the second opening of the serial connection frame body, multiple second connection bodies extending from a circumference of the second bearing cup seat to connect with an inner circumference of the second fan frame body.

3. The series fan frame body structure as claimed in claim 1, wherein the first fan frame body further has a first inlet and a first outlet, the first inlet and first outlet being respectively positioned at two ends of the first passage, the first outlet being mated with the first opening of the serial connection frame body, whereby the first bearing cup seat is proximal to the first outlet, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second outlet being mated with the second opening of the serial connection frame body, whereby the second bearing cup seat is proximal to the second outlet, multiple second connection bodies extending from a circumference of the second bearing cup seat to connect with an inner circumference of the second fan frame body.

4. The series fan frame body structure as claimed in claim 1, wherein the trapezoidal closed peripheral frame of the serial connection frame body has a short side and a long side in parallel to each other, an inclined face and a non-inclined face being connected between the short side and the long side in nonparallel to each other as two opposite faces of the serial connection frame body, the first opening being positioned on the inclined face, while the second opening being positioned on the non-inclined face.
